(19) United States
(12) Patent Application Publication
(10) Pub. No.: US 2024/0413168 A1
(43) Pub. Date: Dec. 12, 2024

(54) ARRAY SUBSTRATE AND DISPLAY APPARATUS

(71) Applicants: FUZHOU BOE OPTOELECTRONICS TECHNOLOGY CO., LTD., Fuzhou, Fujian (CN); BOE Technology Group Co., Ltd., Beijing (CN)

(72) Inventors: Wanping Pan, Beijing (CN); Jianming Huang, Beijing (CN); Yabin Lin, Beijing (CN); Hailong Yu, Beijing (CN); Xuezhen Su, Beijing (CN); Xiaobo Jia, Beijing (CN)

(73) Assignees: FUZHOU BOE OPTOELECTRONICS TECHNOLOGY CO., LTD., Fuzhou, Fujian (CN); BOE Technology Group Co., Ltd., Beijing (CN)

(21) Appl. No.: 18/261,688

(22) PCT Filed: Aug. 12, 2022
(86) PCT No.: PCT/CN2022/111951

§ 371 Date: Jul. 17, 2023

(51) Int. Cl. H01L 27/12; G02F 1/1362; H10K 59/131; H10K 59/35

(52) U.S. Cl. CPC H01L 27/124; G02F 1/136286; H10K 59/131; H10K 59/353

(57) ABSTRACT

An array substrate is provided. The array substrate, in at least a region, includes a plurality of subpixels. A light emissive region of a respective subpixel of the plurality of subpixels has a first end and a second end, the second end being on a side of the first end away from a same reference region with respect to the plurality of subpixels in the region. Directions respectively from second ends to first ends of the plurality of subpixels substantially point toward the same reference region. In the region, pixel-per-inch (PPI) is substantially the same in accordance with a distance away from the same reference region. In the region, the plurality of subpixels include first subpixels of a first orientation and second subpixels of a second orientation. The first orientation and the second orientation are substantially opposite to each other.

### TECHNICAL FIELD

The present invention relates to display technology, more particularly, to an array substrate and a display apparatus.

### BACKGROUND

Liquid crystal display panel has found a wide variety of applications. Typically, a liquid crystal display panel includes a counter substrate and an array substrate facing each other. Thin film transistors, gate lines, data lines, pixel electrodes, common electrodes, and common electrode signal lines are disposed on the array substrate and counter substrate. Between the two substrates, a liquid crystal material is injected to form a liquid crystal layer. One common problem associated with the liquid crystal display panel is light leakage. To prevent light leakage, a black matrix is placed on the counter substrate. A liquid crystal display panel having a larger black matrix can better prevent light leakage. However, an aperture ratio of the liquid crystal display apparatus is reduced by using a black matrix with a larger area.

Organic Light Emitting Diode (OLED) display is driven by a driving current required to be kept constant to control illumination. The OLED display panel includes a plurality of pixel units configured with pixel-driving circuits arranged in multiple rows and columns. Each pixel-driving circuit includes a driving transistor having a gate terminal connected to one gate line per row and a drain terminal connected to one data line per column. When the row in which the pixel unit is gated is turned on, the switching transistor connected to the driving transistor is turned on, and the data voltage is applied from the data line to the driving transistor via the switching transistor, so that the driving transistor outputs a current corresponding to the data voltage to an OLED device. The OLED device is driven to emit light of a corresponding brightness.

### SUMMARY

In one aspect, the present disclosure provides an array substrate, in at least a region, comprising a plurality of subpixels; wherein a light emissive region of a respective subpixel of the plurality of subpixels has a first end and a second end, the second end being on a side of the first end away from a same reference region with respect to the plurality of subpixels in the region; directions respectively from second ends to first ends of the plurality of subpixels substantially point toward the same reference region; and in the region, pixel-per-inch (PPI) is substantially the same in accordance with a distance away from the same reference region; wherein, in the region, the plurality of subpixels comprise first subpixels of a first orientation and second subpixels of a second orientation; a width of a first light emissive region of a respective first subpixel of the first subpixels increases from the first end to the second end; a width of a second light emissive region of a respective second subpixel of the second subpixels decreases from the first end to the second end; and the first orientation and the second orientation are substantially opposite to each other.

Optionally, the array substrate comprises N number of portions sequentially arranged in the region, N being an integer greater than 2; wherein an (n+1)-th portion is on a side of an n-th portion away from the same reference region, 1≤n≤(N−1); and subpixels of the n-th portion that are directly adjacent to the (n+1)-th portion and subpixels of the (n+1)-th portion that are directly adjacent to the n-th portion, where wider ends of light emissive regions of the subpixels of the n-th portion that are directly adjacent to the (n+1)-th portion are directly adjacent to wider ends of light emissive regions of subpixels of the (n+1)-th portion that are directly adjacent to the n-th portion, have different orientations.

Optionally, multiple adjacent subpixels in a respective portion of the N number of portions form a pixel.

Optionally, a respective portion of the N number of portions comprises one or more arcs of subpixels; the array substrate comprises X number of arcs of subpixels at least partially surrounding the same reference region, X being an integer greater than 2; and subpixels respectively from any two directly adjacent arcs of subpixels have different orientations.

Optionally, a 1st portion of the N number of portions comprises one arc of subpixels, the n-th portion comprises two arcs of subpixels, and an N-th portion comprises two arcs of subpixels, and X=2(N−1)+1.

Optionally, a 1st portion of the N number of portions comprises one arc of subpixels, adjacent subpixels along the one arc of subpixels have a same orientation.

Optionally, a ratio of a number of subpixels having first orientations to a number of subpixels having second orientations in the n-th portion is greater than a ratio of a number of subpixels having first orientations to a number of subpixels having second orientations in the (n+1)-th portion.

Optionally, a ratio of a number of subpixels having first orientations to a number of subpixels having second orientations in the n-th portion is in a range of (n−0.5):(n−1) to (n+0.5):(n−1).

Optionally, the subpixels of the n-th portion that are directly adjacent to the (n+1)-th portion have the first orientation; and the subpixels of the (n+1)-th portion that are directly adjacent to the n-th portion have the second orientation.

Optionally, at least a m-th portion of the N number of portions comprises a first sub-portion and a second sub-portion, the second sub-portion being on a side of the first sub-portion away from the same reference region, 1<m<(N−1); and subpixels of the first sub-portion and subpixels of the second sub-portion have different orientations.

Optionally, the subpixels of the first sub-portion have the second orientation; and the subpixels of the second sub-portion have the first orientation.

Optionally, a number of subpixels in the n-th portion is S*I*(2n−1); S stands for a number of subpixels in a respective pixel; and I stands for a number of subpixels in a 1st portion of the N number of portions divided by S, the 1st portion being a portion of the N number of portions closest to the same reference region.

Optionally, the array substrate comprises at least N number of gate lines and at least (J*N) number of data lines; wherein a respective gate line of (N−1) number of gate line out of the N number of gate lines is between two adjacent portions of the N number of portions; and J stands for a number of subpixels in a 1st portion of the N number of portions, the 1st portion being a portion of the N number of portions closest to the same reference region.

Optionally, the array substrate comprises (2N−1) number of gate lines and (J*N) number of data lines.

Optionally, a 1st gate line of the (2N−1) number of gate lines is configured to provide gate driving signals to the subpixels in the 1st portion; and a respective portion of a 2nd portion to the N-th portion of the N number of portions is configured to receive gate driving signals from two gate lines.

Optionally, the (J*N) number of data lines comprise J number of sets of data lines, a respective set of the J number of sets of data lines comprising N number of data lines; and an n-th data line in the respective set is configured to provide data signals to one or more subpixels in n number of portions of the N number of portions, 1≤n≤N.

Optionally, an N-th data line of the N number of data lines in the respective set is configured to provide data signals to a row of subpixels in the N number of portions, respectively; a 1st data line of the N number of data lines in the respective set is configured to provide data signals to two subpixels in the N-th portion of the N number of portions; and an n′-th data line of the N number of data lines in the respective set is configured to provide data signals to two rows of subpixels in n′ number of portions of the N number of portions, respectively, 1<n′<N.

Optionally, a respective set of the J number of sets of data lines comprises N number of data lines; in a j′-th set of the J number of sets of data lines, 1<j′<J, two subpixels in a same portion, each having at least 40% of an elongated side directly adjacent to the N-th data line, have a same orientation; and in the j′-th set of the J number of sets of data lines, 1<j′<J, two subpixels in a same portion, each having at least 40% of an elongated side directly adjacent to an n″-th data line of the N number of data lines, have a same orientation, 1≤n″<N.

Optionally, the array substrate comprises N number of gate lines and (J*(2N−1)) number of data lines.

Optionally, the respective gate line is configured to provide gate driving signals to the two adjacent portions of the N number of portions.

Optionally, the (J*(2N−1)) number of data lines comprise I number of sets of data lines, a respective set of the I number of sets of data lines comprising (2N−1) number of data lines; a (2n′−1)-th data line in the respective set is configured to provide data signals to one or more subpixels in n′ number of portions of the N number of portions, 1<n′<N; and a 2n′-th data line in the respective set is configured to provide data signals to one or more subpixels in n′ number of portions of the N number of portions.

Optionally, a 1st data line in the respective set is configured to provide data signals to a row of subpixels in the N number of portions, respectively; the (2n′−1)-th data line in the respective set is configured to provide data signals to a row of first subpixels in n′ number of portions of the N number of portions, respectively, 1<n′<N; and the 2n′-th data line in the respective set is configured to provide data signals to a row of second subpixels in n′ number of portions of the N number of portions, respectively.

Optionally, the array substrate comprises M number of gate lines arranged is M number of partial circles surrounding the same reference region; and (M−1) number of connecting lines; wherein the (M−1) number of connecting lines are in a layer different from the M number of gate lines; a i-th connecting line of the (M−1) number of connecting lines electrically connects a (i+1)-th gate line to a gate-on-array, 1≤i≤(M−1); and the i-th connecting line crosses over i number of gate lines.

Optionally, the (M−1) number of connecting lines are in a same layer as the at least (J*N) number of data lines.

Optionally, respective areas of the subpixels in the region are substantially the same.

Optionally, a number of subpixels in the N number of portions increases in accordance with a distance away from the same reference region.

Optionally, a width of the same reference region is less than two times of a maximum length of a respective subpixel.

In another aspect, the present disclosure provides a display apparatus, comprising the array substrate described herein or fabricated by a method described herein, and one or more integrated circuits connected to the array substrate.

Optionally, the display apparatus has a circular shape.

### BRIEF DESCRIPTION OF THE FIGURES

The following drawings are merely examples for illustrative purposes according to various disclosed embodiments and are not intended to limit the scope of the present invention.

FIG. 1 is a schematic diagram illustrating the structure of an array substrate in some embodiments according to the present disclosure.

FIG. 2 is a schematic diagram illustrating the structure of a shape of a respective subpixel in some embodiments according to the present disclosure.

FIG. 3 is a schematic diagram illustrating the structure of an array substrate in some embodiments according to the present disclosure.

FIG. 4A is a schematic diagram illustrating an arrangement of pixels in an array substrate in some embodiments according to the present disclosure.

FIG. 4B illustrates N number of portions of an array substrate in some embodiments according to the present disclosure.

FIG. 5 illustrates subpixels of different orientations in an array substrate in some embodiments according to the present disclosure.

FIG. 6A is a schematic diagram illustrating the structure of a region in an array substrate in some embodiments according to the present disclosure.

FIG. 6B is a schematic diagram illustrating arcs of subpixels in an array substrate in some embodiments according to the present disclosure.

FIG. 7 illustrates orientations of subpixels in different portions of an array substrate in some embodiments according to the present disclosure.

FIG. 8 illustrates orientations of subpixels in sub-portions of an individual portion of an array substrate in some embodiments according to the present disclosure.

FIG. 9A illustrates a layout of gate lines and data lines in an array substrate in some embodiments according to the present disclosure.

FIG. 9B illustrates a layout of data lines in the array substrate depicted in FIG. 9A.

FIG. 9C illustrates rows of subpixels connected to a respective set of data lines in an array substrate in some embodiments according to the present disclosure.

FIG. 9D illustrates subpixels in an array substrate in some embodiments according to the present disclosure.

FIG. 9E illustrates subpixels in an array substrate in some embodiments according to the present disclosure.

FIG. 9F illustrates a row of subpixels rN in some embodiments according to the present disclosure.

FIG. 9G illustrates a row of subpixels rn′1 in n′ number of portions of the N number of portions, respectively.

FIG. 9H illustrates a row of subpixels m′1 in n′ number of portions of the N number of portions, respectively.

FIG. 9I illustrates a layout of gate lines and data lines in an array substrate in some embodiments according to the present disclosure.

FIG. 10A illustrates a layout of gate lines and data lines in an array substrate in some embodiments according to the present disclosure.

FIG. 10B illustrates a layout of data lines in the array substrate depicted in FIG. 10A.

FIG. 10C illustrates rows of subpixels connected to a respective set of data line in an array substrate in some embodiments according to the present disclosure.

FIG. 10D illustrates a row of subpixels r (2N−1) in some embodiments according to the present disclosure.

FIG. 10E illustrates a row of first subpixels rsp1 in n′ number of portions of the N number of portions, respectively.

FIG. 10F illustrates a row of second subpixels rsp2 in n′ number of portions of the N number of portions, respectively.

FIG. 11A illustrates a layout of signal lines in an array substrate in some embodiments according to the present disclosure.

FIG. 11B illustrates a layout of gate lines in an array substrate in some embodiments according to the present disclosure.

FIG. 11C illustrates a layout of data lines in an array substrate in some embodiments according to the present disclosure.

FIG. 12 is a cross-sectional view along an A-A′ line in FIG. 11A.

FIG. 13 illustrates several defects along a curved edge in a related display panel.

FIG. 14 is a diagram illustrating the structure of a liquid crystal display apparatus in some embodiments according to the present disclosure.

FIG. 15 illustrates a detailed structure in a display area in a light emitting diode display apparatus in some embodiments according to the present disclosure.

### DETAILED DESCRIPTION

The disclosure will now be described more specifically with reference to the following embodiments. It is to be noted that the following descriptions of some embodiments are presented herein for purpose of illustration and description only. It is not intended to be exhaustive or to be limited to the precise form disclosed.

The present disclosure provides, inter alia, an array substrate and a display apparatus that substantially obviate one or more of the problems due to limitations and disadvantages of the related art. In one aspect, the present disclosure provides an array substrate. In some embodiments, the array substrate, in at least a region, includes a plurality of subpixels. Optionally, a light emissive region of a respective subpixel of the plurality of subpixels has a first end and a second end, the second end being on a side of the first end away from a same reference region with respect to the plurality of subpixels in the region. Optionally, directions respectively from second ends to first ends of the plurality of subpixels substantially point toward the same reference region. Optionally, in the region, pixel-per-inch (PPI) is substantially the same in accordance with a distance away from the same reference region. Optionally, in the region, the plurality of subpixels comprise first subpixels of a first orientation and second subpixels of a second orientation. Optionally, a width of a first light emissive region of a respective first subpixel of the first subpixels increases from the first end to the second end. Optionally, a width of a second light emissive region of a respective second subpixel of the second subpixels decreases from the first end to the second end. Optionally, the first orientation and the second orientation are substantially opposite to each other.

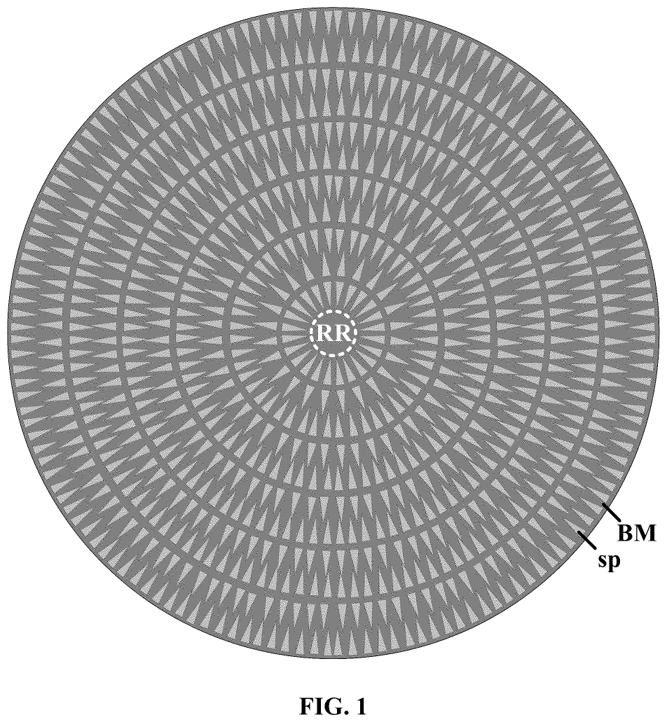

FIG. 1 is a schematic diagram illustrating the structure of an array substrate in some embodiments according to the present disclosure. Referring to FIG. 1, the array substrate includes a plurality of subpixels sp. The plurality of subpixels sp surround a same reference region RR. FIG. 1 shows an array substrate in which the plurality of subpixels sp are arranged in multiple rings, each of which surrounds the same reference region RR. In one particular example, the multiple rings surrounds a same reference center, for example, the multiple rings are co-centric.

A respective subpixel of the plurality of subpixels sp may have various appropriate shapes. Examples of appropriate shapes include a rectangular shape, a square shape, a triangular shape, a polygonal shape, and an irregular shape. In one example, the respective subpixel has an elongated shape in which a width increases or decreases along a longitudinal direction of the elongated shape. In one example, a width at one end of the elongated shape is substantially zero. As used herein, the term “subpixel” refers to a portion of a pixel which can be independently addressable to emit a specific color (e.g., red, green, blue, or white).

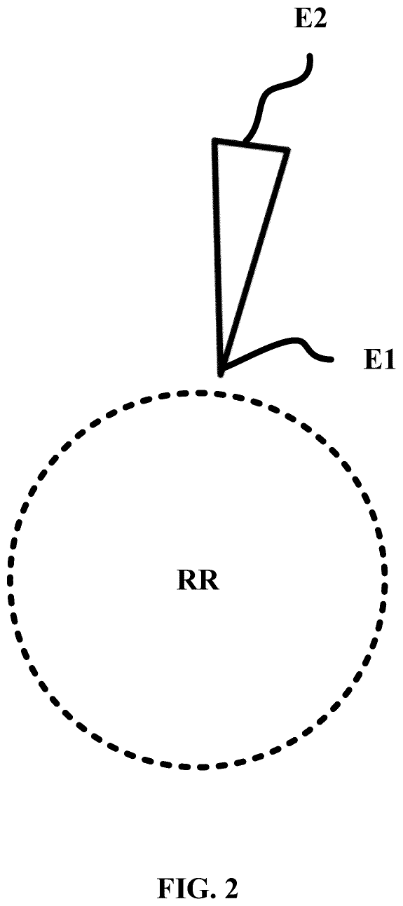

FIG. 2 is a schematic diagram illustrating the structure of a shape of a respective subpixel in some embodiments according to the present disclosure. Referring to FIG. 2, a light emissive region of a respective subpixel of the plurality of subpixels sp has a first end E1 and a second end E2. The second end E2 is on a side of the first end E1 away from a same reference region RR with respect to the plurality of subpixels sp in at least a region of the array substrate.

Referring to FIG. 1 and FIG. 2, the plurality of subpixels sp may be oriented in various different directions. However, directions respectively from second ends to first ends of light emissive regions of the plurality of subpixels sp substantially point toward the same reference region RR. As used herein, the term “substantially point toward” refers to that an extension direction of a line connecting a middle point of a side of the light emissive region of the respective subpixel at the second end and a middle point of a side of the light emissive region of the respective subpixel at the first end crosses over the same reference region RR.

The same reference region RR may have various appropriate shape. Examples of appropriate shapes of the same reference region RR include a circular shape, a square shape, a rectangular shape, an elliptical shape, a triangular shape, a polygonal shape, and an irregular shape. The same reference region RR may have various appropriate sizes. In some embodiments, a width of the same reference region RR is less than ten times of a maximum length of a respective subpixel, e.g., less than nine times of a maximum length of a respective subpixel, less than eight times of a maximum length of a respective subpixel, less than seven times of a maximum length of a respective subpixel, less than six times of a maximum length of a respective subpixel, less than five times of a maximum length of a respective subpixel, less than four times of a maximum length of a respective subpixel, less than three times of a maximum length of a respective subpixel, less than two times of a maximum length of a respective subpixel, or less than a maximum length of a respective subpixel.

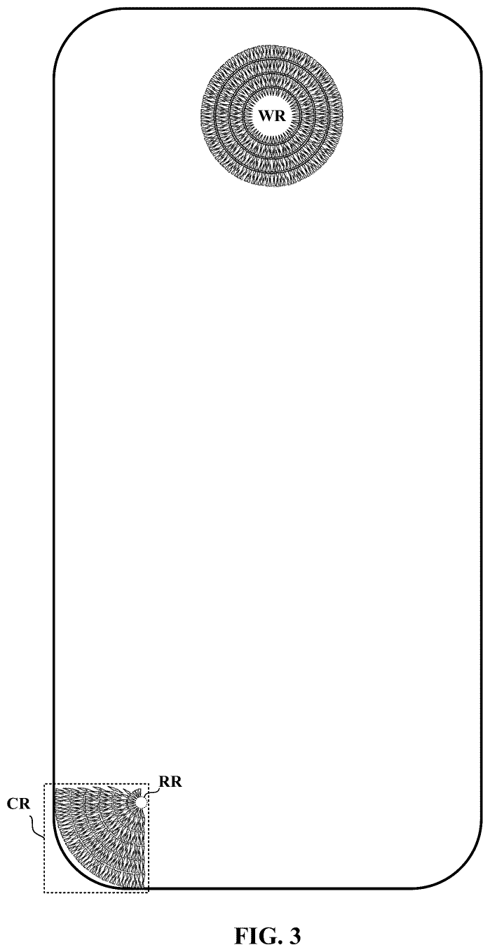

In some embodiments, the plurality of subpixels sp and the above discussed arrangement are limited to a region of the array substrate. FIG. 3 is a schematic diagram illustrating the structure of an array substrate in some embodiments according to the present disclosure. Referring to FIG. 3, in some embodiments, the array substrate in a corner region CR includes a plurality of subpixels sp. The same reference region RR with respect to the plurality of subpixels sp in the corner region CR is a region adjacent to a corner of the array substrate.

In another example, referring to FIG. 3, the array substrate includes a plurality of subpixels sp surrounding a window region WR in the array substrate. The window region WR may be a region for installing a component such as a camera or a fingerprint sensor underneath light emitting elements. The same reference region may be the window region WR.

The array substrate may have various appropriate shapes. In one example as illustrated in FIG. 1, the array substrate has a circular shape. Examples of appropriate shapes of the array substrate further includes a square shape, a rectangular shape, an elliptical shape, a triangular shape, a polygonal shape, and an irregular shape.

Referring to FIG. 1, the array substrate in some embodiments further includes a black matrix in an inter-subpixel region of the array substrate.

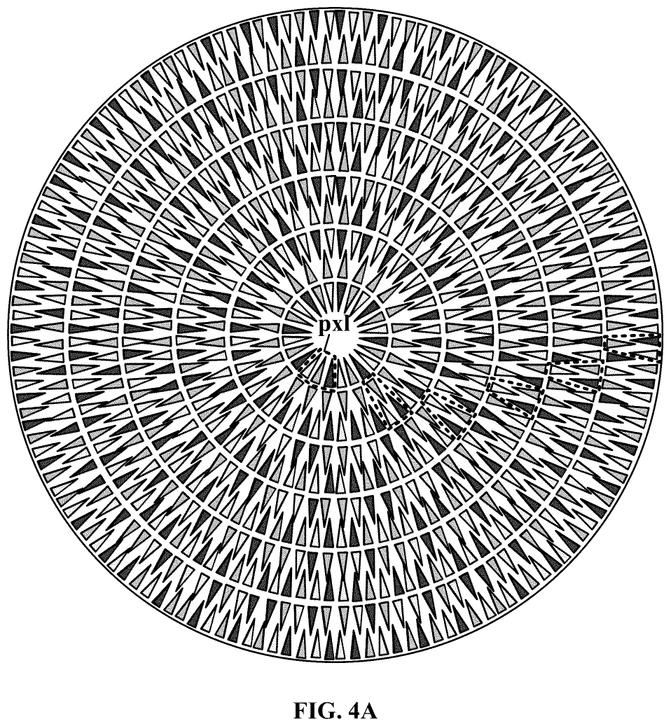

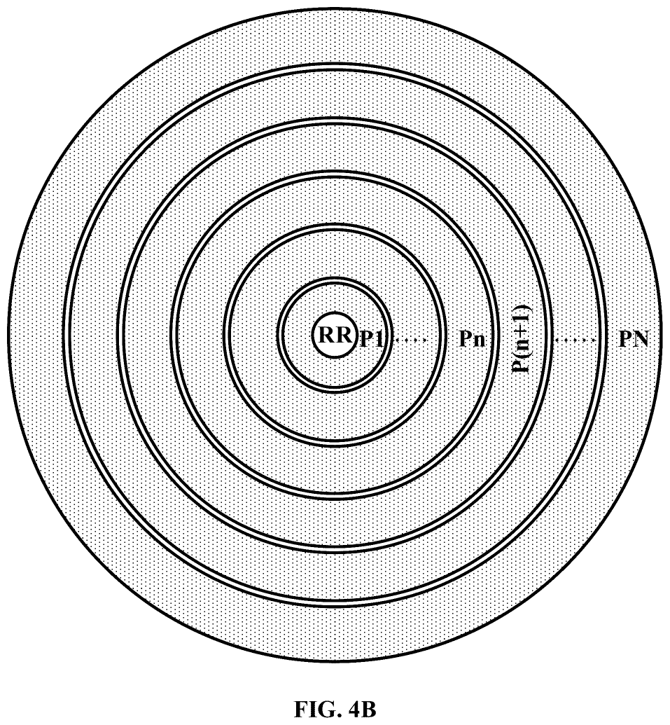

FIG. 4A is a schematic diagram illustrating an arrangement of pixels in an array substrate in some embodiments according to the present disclosure. Referring to FIG. 4A, the array substrate includes a plurality of pixels pxl, each pixel including one or more subpixels. FIG. 4A illustrates an example in which an individual pixel includes three subpixels of different colors, e.g., a red subpixel, a green subpixel, and a blue subpixel. In different portions of the array substrate, the pixel arrangement may be different.

FIG. 4B illustrates N number of portions of an array substrate in some embodiments according to the present disclosure. FIG. 4B depicts portions of an array substrate corresponding to the array substrate depicted in FIG. 4A. Referring to FIG. 4A and FIG. 4B, the array substrate in some embodiments includes N number of portions (P1, . . . , Pn, . . . , PN) sequentially arranged in the region, N being an integer greater than 2. The 1st portion P1 surrounds the same reference region RR, the second portion surrounds the 1st portion P1, the n-th portion Pn surrounds the (n−1)-th portion, and the N-th portion PN surrounds the (N−1)-th portion.

In some embodiments, referring to FIG. 4A, in the region, a number of subpixels in a unit area is substantially the same in accordance with a distance away from the same reference region RR. For example, in the region, pixel-per-inch (PPI) is substantially the same in accordance with a distance away from the same reference region RR. As used herein, the term “substantially the same” refers to a difference between two values not exceeding 10% of a base value (e.g., one of the two values), e.g., not exceeding 8%, not exceeding 6%, not exceeding 4%, not exceeding 2%, not exceeding 1%, not exceeding 0.5%, not exceeding 0.1%, not exceeding 0.05%, and not exceeding 0.01%, of the base value. In some embodiments, respective areas of the subpixels in the region are substantially the same. In some embodiments, a number of subpixels in the N number of portions increases in accordance with a distance away from the same reference region RR.

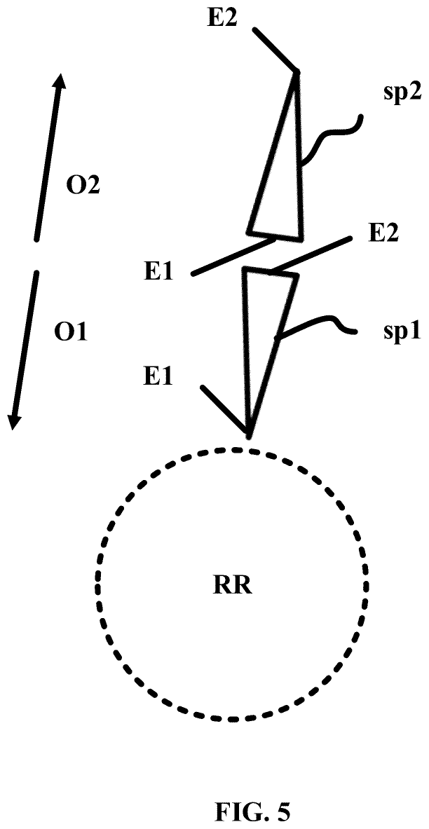

FIG. 5 illustrates subpixels of different orientations in an array substrate in some embodiments according to the present disclosure. Referring to FIG. 1, FIG. 2, and FIG. 5, the plurality of subpixels sp in some embodiments include first subpixels sp1 of a first orientation O1 and second subpixels of a second orientation O2. A width of a light emissive region of a respective first subpixel of the first subpixels sp1 increases from the first end E1 to the second end E2. A width of a light emissive region of a respective second subpixel of the second subpixels sp2 decreases from the first end E1 to the second end E2. In one example, the first orientation O1 and the second orientation O2 are substantially opposite to each other. As used herein, the term “substantially opposite” refers to two orientations having an offset angle in a range of 70 degrees to 110 degrees, e.g., 70 degrees to 75 degrees, 75 degrees to 80 degrees, 80 degrees to 85 degrees, 85 degrees to 90 degrees, 90 degrees to 95 degrees, 95 degrees to 100 degrees, 100 degrees to 105 degrees, or 105 degrees to 110 degrees.

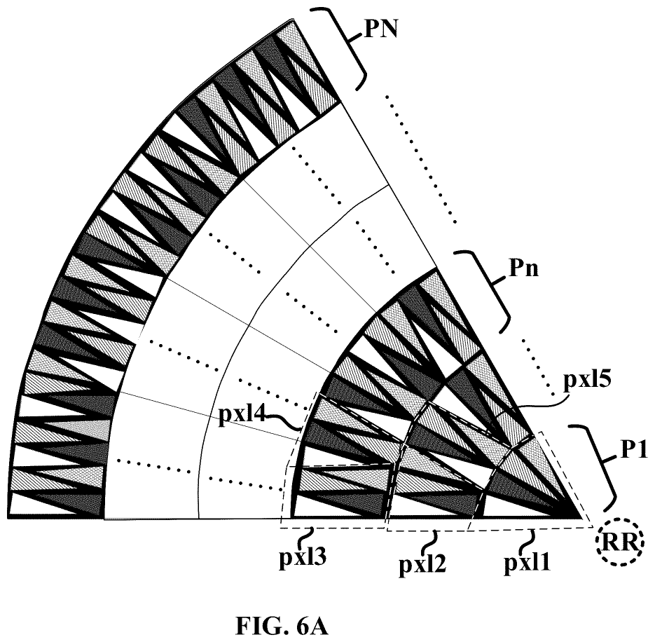

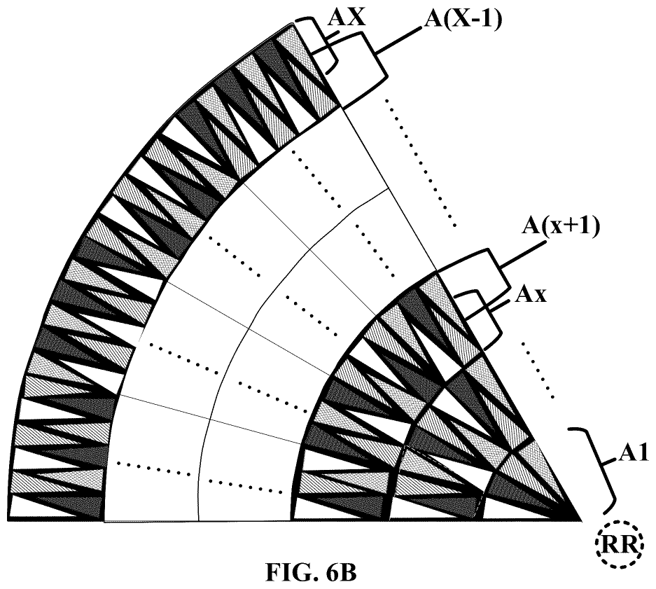

FIG. 6A is a schematic diagram illustrating the structure of a region in an array substrate in some embodiments according to the present disclosure. Referring to FIG. 6A, the array substrate includes a plurality of pixels (e.g., pxl1, pxl2, pxl3, pxl4, and pxl5 as depicted in FIG. 6A), each pixel including one or more subpixels. FIG. 6A illustrates an example in which an individual pixel includes four subpixels of different colors, e.g., a red subpixel, a green subpixel, a blue subpixel, and a white subpixel. Optionally, multiple adjacent subpixels in a respective portion of the N number of portions form a pixel.

Referring to FIG. 4B and FIG. 6A, the N number of portions (P1, . . . , Pn, . . . , PN) are sequentially arranged in the region. In some embodiments, an (n+1)-th portion P (n+1) is on a side of an n-th portion Pn away from the same reference region, 1≤n≤(N−1). In some embodiments, subpixels of the n-th portion Pn that are directly adjacent to the (n+1)-th portion P (n+1) and subpixels of the (n+1)-th portion P (n+1) that are directly adjacent to the n-th portion Pn, where wider ends of light emissive regions of the subpixels of the n-th portion that are directly adjacent to the (n+1)-th portion are directly adjacent to wider ends of light emissive regions of subpixels of the (n+1)-th portion that are directly adjacent to the n-th portion, have different orientations.

Alternatively, in some embodiments, subpixels of the n-th portion Pn that are directly adjacent to the (n+1)-th portion P (n+1) and subpixels of the (n+1)-th portion P (n+1) that are directly adjacent to the n-th portion Pn, where narrower ends of light emissive regions of the subpixels of the n-th portion that are directly adjacent to the (n+1)-th portion are directly adjacent to narrower ends of light emissive regions of subpixels of the (n+1)-th portion that are directly adjacent to the n-th portion, have different orientations.

In some embodiments, a ratio of a number of subpixels having first orientations to a number of subpixels having second orientations in the n-th portion is greater than a ratio of a number of subpixels having first orientations to a number of subpixels having second orientations in the (n+1)-th portion. Optionally, the 1st portion includes exclusively multiple subpixels of first orientation. Optionally, a ratio of a number of subpixels having first orientations to a number of subpixels having second orientations in the 2nd portion is in a range between 1.5:1 to 2.5:1, e.g., 2:1. Optionally, a ratio of a number of subpixels having first orientations to a number of subpixels having second orientations in the 3rd portion is in a range of 2.5:2 to 3.5:2, e.g., 3:2. Optionally, a ratio of a number of subpixels having first orientations to a number of subpixels having second orientations in the n-th portion is in a range of (n−0.5):(n−1) to (n+0.5):(n−1), e.g., n: (n−1). Optionally, a ratio of a number of subpixels having first orientations to a number of subpixels having second orientations in the (n+1)-th portion is in a range of (n+1−0.5):n to (n+1+0.5):n, e.g., (n+1):n.

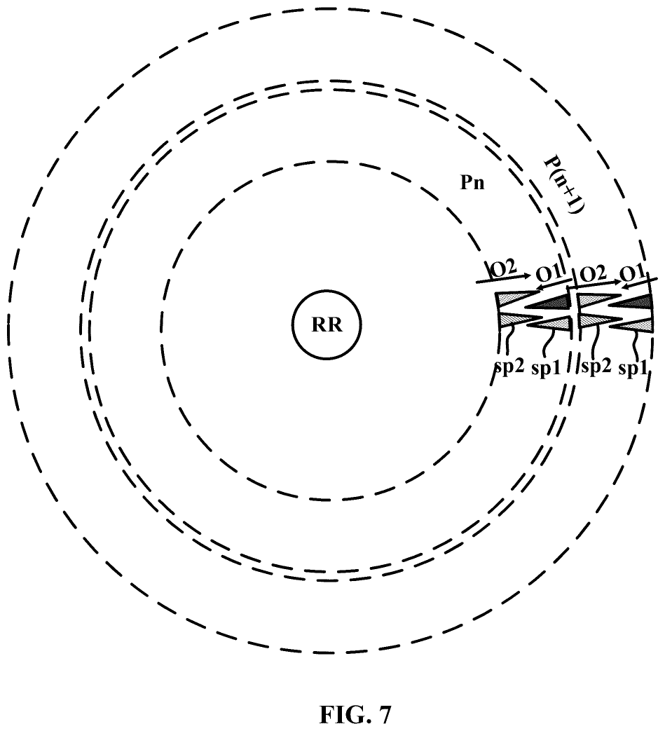

FIG. 7 illustrates orientations of subpixels in different portions of an array substrate in some embodiments according to the present disclosure. FIG. 7 only shows selected few subpixels in the n-th portion Pn and the (n+1)-th portion P (n+1) for illustration purpose. Referring to FIG. 4A, FIG. 4B, and FIG. 7, the n-th portion Pn includes two circles of subpixels. In the n-th portion Pn, the circle of subpixels directly adjacent to the (n+1)-th portion P (n+1) are first subpixels sp1 of the first orientation O1, and the circle of subpixels not directly adjacent to the (n+1)-th portion P (n+1) (e.g., subpixels adjacent to the (n−1)-th portion) are second subpixels sp2 of the second orientation O2. The (n+1)-th portion P (n+1) also includes two circles of subpixels. In the (n+1)-th portion P (n+1), the circle of subpixels directly adjacent to the n-th portion Pn are second subpixels sp2 of the second orientation O2, and the circle of subpixels not directly adjacent to the n-th portion Pn (e.g., subpixels adjacent to the (n+2)-th portion) are first subpixels sp1 of the first orientation O1. Subpixels of the n-th portion Pn that are directly adjacent to the (n+1)-th portion P (n+1) and subpixels of the (n+1)-th portion P (n+1) that are directly adjacent to the n-th portion Pn have different orientations, e.g., substantially opposite orientations.

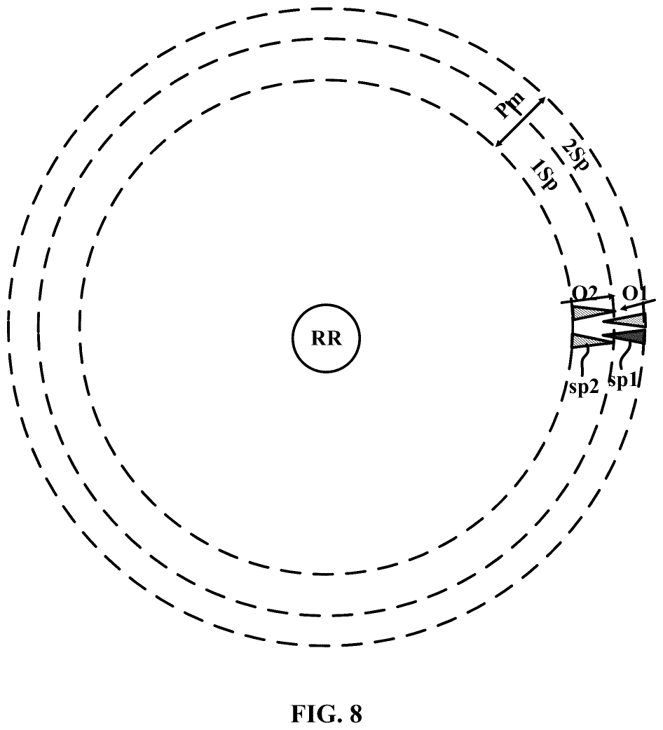

FIG. 8 illustrates orientations of subpixels in sub-portions of an individual portion of an array substrate in some embodiments according to the present disclosure. FIG. 8 only shows selected few subpixels in a m-th portion Pm for illustration purpose. Referring to FIG. 8, at least a m-th portion Pm of the N number of portions includes a first sub-portion 1Sp and a second sub-portion 2Sp. Optionally, 1<m<(N−1). Optionally, 1<m≤(N−1). Optionally, 1≤m≤(N−1). The second sub-portion 2Sp is on a side of the first sub-portion 1Sp away from the same reference region RR.

In some embodiments, subpixels of the first sub-portion 1Sp and subpixels of the second sub-portion 2Sp have different orientations. Referring to FIG. 8, subpixels of the first sub-portion 1Sp are second subpixels sp2 of the second orientation O2; and subpixels of the second sub-portion 2Sp are first subpixels sp1 of the first orientation O1.

In some embodiments, referring to FIG. 6A, the N number of portions are arranged along N number of arcs, respectively. The N number of arcs at least partially surround the same reference region RR. As used herein, the term “arc” is not limited to part of a true circle, and may be part of an ellipse, may be a U shape, may be a C shape, may be part of a hyperbola, may be part of a sine curve, or may be interpreted as including a series of straight segments in end to end, angularly related pattern, forming a generally angularly arced shape, as well as a smoothly curved shape.

In some embodiments, referring to FIG. 4A and FIG. 4B, the N number of arcs are N number of circles, respectively. The same reference region RR is a same central region with respect to N number of circles along which the N number of portions are arranged, respectively. The N number of circles substantially surround the same central region.

In some embodiments, a number of subpixels in the n-th portion is S*I*(2n−1), wherein S stands for a number of subpixels in a respective pixel; and I stands for a number of subpixels in a 1st portion of the N number of portions divided by S, the 1st portion being a portion of the N number of portions closest to the same reference region.

Referring to FIG. 6A, in one example, a respective pixel includes four subpixels, e.g., S=4. The 1st portion P1 of the N number of portions includes four subpixels, e.g., I=4/4. A number of subpixels in the n-th portion is 4*4/4*(2n−1). For example, the 1st portion P1 include 4 subpixels, the 2nd portion include 12 subpixels, and the third portion includes 20 subpixels.

Referring to FIG. 4A and FIG. 4B, a respective pixel includes three subpixels, e.g., S=3. The 1st portion P1 of the N number of portions includes 24 subpixels, e.g., I=24/3. A number of subpixels in the n-th portion is 3*24/3*(2n−1). For example, the 1st portion P1 include 24 subpixels, the 2nd portion include 72 subpixels, and the third portion includes 120 subpixels.

In some embodiments, a respective portion of the N number of portions comprises one or more arcs of subpixels, as shown in FIG. 1, FIG. 4A, and FIG. 6A. A respective portion of the N number of portions comprises one or more arcs of subpixels. Optionally, the respective portion of the N number of portions comprises y number of arcs of subpixels, y being an integer ≥1. For example, the 1st portion includes one arc of subpixels, the n-th portion Pn includes two arcs of subpixels, and the N-th portion includes two arcs of subpixels, as shown in FIG. 6A. The array substrate includes X number of arcs of subpixels at least partially surround the same reference region RR. Optionally, subpixels respectively from any two directly adjacent arcs of subpixels have different orientations. The X number of arcs of subpixels have alternate orientations.

In some embodiments, a 1st portion of the N number of portions comprises one arc of subpixels, adjacent subpixels along the one arc of subpixels have a same orientation. In one example, referring to FIG. 6A, the 1st portion of the N number of portions includes only one arc of subpixels. The 1st portion includes a red subpixel, a green subpixel, a blue subpixel, and a white subpixel adjacent to each other. The red subpixel, the green subpixel, the blue subpixel, and the white subpixel in the 1st portion form a pixel.

FIG. 6B is a schematic diagram illustrating arcs of subpixels in an array substrate in some embodiments according to the present disclosure. Referring to FIG. 6B, in the region, the array substrate includes X number of arcs of subpixels (e.g., A1, . . . , Ax, A(x+1), . . . , A(X−1), AX) at least partially surround the same reference region RR. In some embodiments, any adjacent two subpixels in a same arc have a same orientation. Optionally, subpixels respectively from any two directly adjacent arcs of subpixels have different orientations. For example, subpixels in the Ax and subpixels in the A(x+1) have different orientations. The X number of arcs of subpixels have alternate orientations. As used herein, the term “arc” refers to any appropriate arc of a shape, e.g., a double arc shape. In one example, in the context of arcs of subpixels, the arc may refer to a virtual line crossing over wider ends of light emissive regions of subpixels. In another example, the arc may refer to a virtual line crossing over narrower ends of light emissive regions of subpixels. In another example, the arc refers to a virtual line crossing over centers of light emissive regions of subpixels.

In some embodiments, the array substrate further includes a plurality of thin film transistors, a plurality of gate lines configured to provide gate driving signals to the plurality of thin film transistors, and a plurality of data lines configured to provide data signals to the plurality of thin film transistors.

In some embodiments, the array substrate includes at least N number of gate lines and at least (J*N) number of data lines. A respective gate line of (N−1) number of gate line out of the N number of gate lines is between two adjacent portions of the N number of portions. J stands for a number of subpixels in a 1st portion of the N number of portions, the 1st portion being a portion of the N number of portions closest to the same reference region.

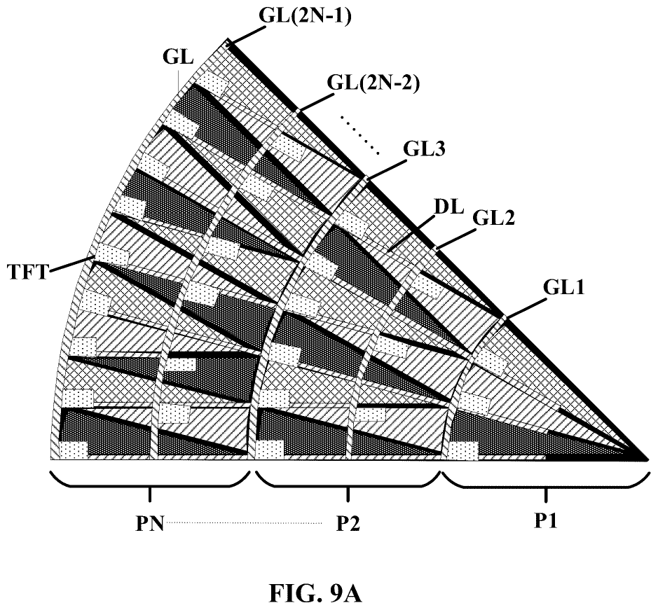

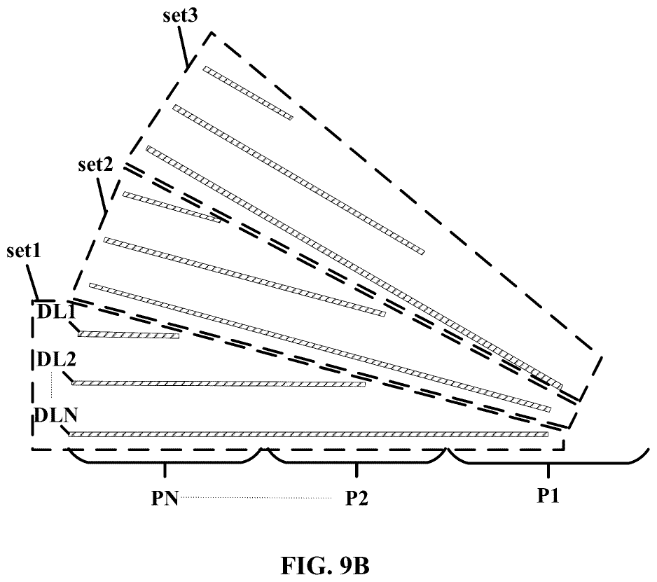

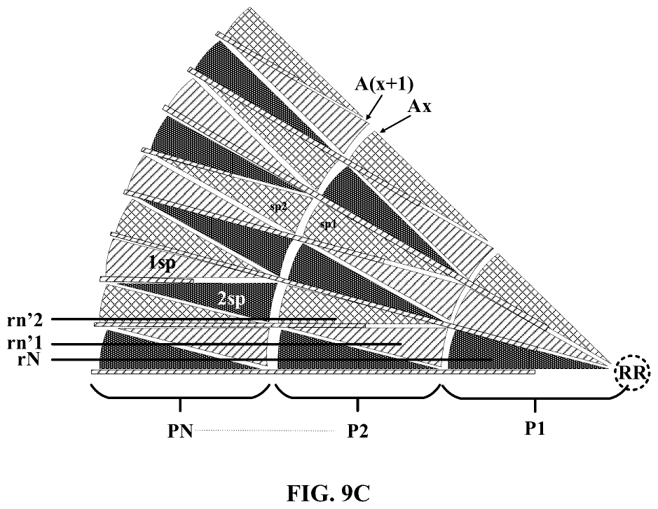

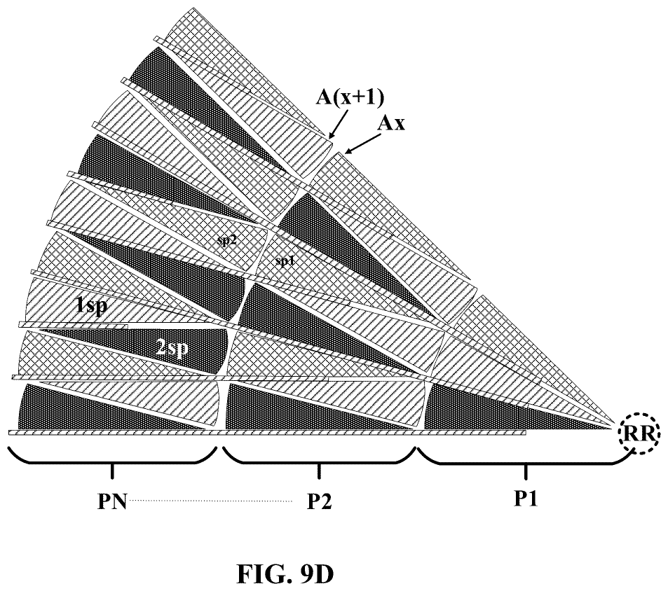

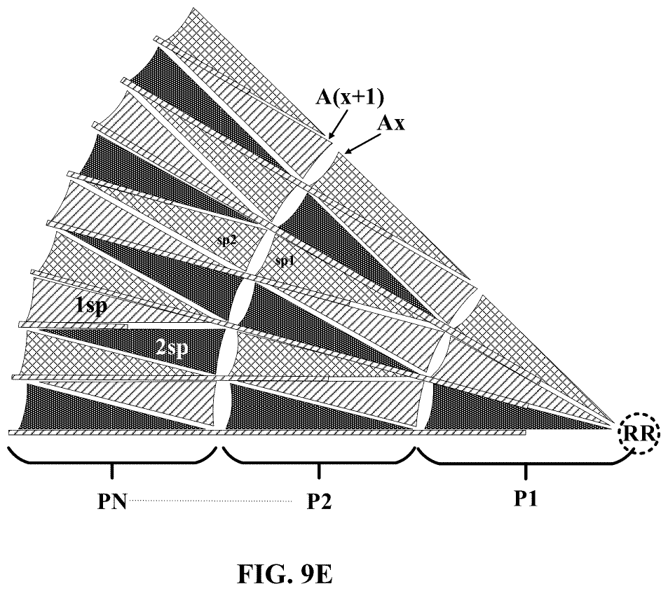

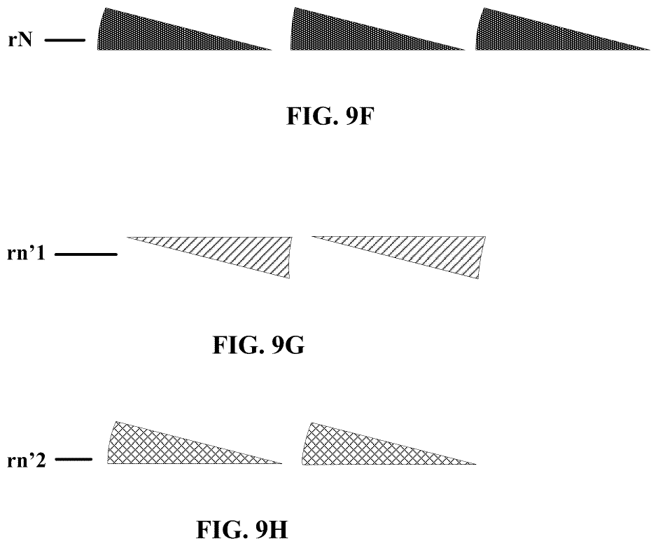

FIG. 9A illustrates a layout of gate lines and data lines in an array substrate in some embodiments according to the present disclosure. Referring to FIG. 9A, the array substrate in some embodiments includes N number of portions (P1 to PN). In some embodiments, the array substrate includes (2N−1) number of gate lines GL and (J*N) number of data lines DL. J stands for a number of subpixels in a 1st portion of the N number of portions.

In some embodiments, a 1st gate line GL1 of the (2N−1) number of gate lines GL is configured to provide gate driving signals to the subpixels in the 1st portion P1. A respective portion of a 2nd portion P2 to the N-th portion PN of the N number of portions is configured to receive gate driving signals from two gate lines. Referring to FIG. 9A, the 2nd portion P2 is configured to receive gate driving signals from gate lines GL2 and GL3; and the N-th portion PN is configured to receive gate driving signals from gate lines GL (2N−2) and GL (2N−1).

In some embodiments, the (J*N) number of data lines includes J number of sets of data lines, a respective set of the J number of sets of data lines including N number of data lines. FIG. 9B illustrates a layout of data lines in the array substrate depicted in FIG. 9A. Referring to FIG. 9A and FIG. 9B, in one example, a number of subpixels in a 1st portion P1 of the N number of portions is 3, e.g., J=3. The (J*N) number of data lines includes three sets of data lines, e.g., set1, set2, set3. A respective set of the J number of sets of data lines includes N number of data lines. For example, the first set of data line set1 includes N number of data lines, DL1, DL2, . . . , DLN.

In some embodiments, an n-th data line in the respective set is configured to provide data signals to one or more subpixels in n number of portions of the N number of portions, 1≤ n≤N. Referring to FIG. 9A and FIG. 9B, a 1st data line DL1 is configured to provide data signals to one or more subpixels in a single portion (PN) of the N number of portions. The 2nd data line DL2 is configured to provide data signals to one or more subpixels in two portions (PN and P(N−1)) of the N number of portions. The N-th data line DLN is configured to provide data signals to one or more subpixels in N number of portions (P1 to PN) of the N number of portions.

FIG. 9C illustrates rows of subpixels connected to a respective set of data line in an array substrate in some embodiments according to the present disclosure. In some embodiments, referring to FIG. 9A to FIG. 9C, an N-th data line DLN of the N number of data lines in the respective set (e.g., set 1) is configured to provide data signals to a row of subpixels rN in the N number of portions, respectively. A 1st data line of the N number of data lines in the respective set is configured to provide data signals to two subpixels (e.g., 1sp and 2sp in FIG. 9C) in the N-th portion of the N number of portions. An n′-th data line of the N number of data lines in the respective set is configured to provide data signals to two rows of subpixels (e.g., rn′1 and m′2 in FIG. 9C) in n′ number of portions of the N number of portions, respectively, 1<n′<N. For example, when n′=2, the 2nd data line DL2 of the N number of data lines in the respective set is configured to provide data signals to two rows (e.g., PN and P(N−1) in FIG. 9C) of subpixels in two portions of the N number of portions, respectively. FIG. 9F illustrates a row of subpixels rN in some embodiments according to the present disclosure. FIG. 9G illustrates a row of subpixels rn′1 in n′ number of portions of the N number of portions, respectively. FIG. 9H illustrates a row of subpixels rn′1 in n′ number of portions of the N number of portions, respectively. As used herein, the term “a row of subpixels” refers to multiple subpixels having a substantially same orientation and are coupled to a same data line.

Referring to FIG. 9A and FIG. 9B, in a j′-th set of the J number of sets of data lines, 1<j′<J, two subpixels in a same portion, each having at least 40% (e.g., at least 50%, at least 60%, at least 70%, at least 80%, at least 90%, at least 95%, at least 98%, at least 99%, or 100%) of an elongated side directly adjacent to the N-th data line DLN, have a same orientation (e.g., the first orientation). Optionally, in the j′-th set of the J number of sets of data lines, 1<j′<J, two subpixels in a same portion, each having at least 40% (e.g., at least 50%, at least 60%, at least 70%, at least 80%, at least 90%, at least 95%, at least 98%, at least 99%, or 100%) of an elongated side directly adjacent to an n″-th data line of the N number of data lines, have a same orientation (e.g., the first orientation), 1≤n″<N.

Referring to FIG. 9C, in some embodiments, first subpixels sp1 in an Ax arc and second subpixels sp2 in an A(x+1) arc have different shapes, the Ax arc and the A(x+1) arc are directly adjacent to each other. In some embodiments, a wider end of a light emissive region of a respective first subpixel of the first subpixels sp1 in the Ax arc and a wider end of a light emissive region of a respective second subpixel of the second subpixels sp2 in the A(x+1) arc are adjacent to each other. For example, a narrower end of a light emissive region of the respective first subpixel of the first subpixels sp1 in the Ax arc is on a side of the wider end of a respective first subpixel of the first subpixels sp1 in the Ax arc away from the respective second subpixel of the second subpixels sp2 in the A(x+1) arc; and a narrower end of a light emissive region of the respective second subpixel of the second subpixels sp2 in the A(x+1) arc is on a side of the wider end of a light emissive region of a respective second subpixel of the second subpixels sp2 in the A(x+1) arc away from the respective first subpixel of the first subpixels sp1 in the Ax arc. The respective second subpixel of the second subpixels sp2 in the A(x+1) arc is on a side of the respective first subpixel of the first subpixels sp1 in the Ax arc away from the same reference region RR. In some embodiments, the wider end of the light emissive region of the respective first subpixel of the first subpixels sp1 in the Ax arc has a convex shape protruding toward the wider end of the light emissive region of the respective second subpixel of the second subpixels sp2 in the A(x+1) arc. In some embodiments, the wider end of the light emissive region of the respective second subpixel of the second subpixels sp2 in the A(x+1) arc has a concave shape recessing away from the wider end of the light emissive region of the respective first subpixel of the first subpixels sp1 in the Ax arc.

FIG. 9D illustrates subpixels in an array substrate in some embodiments according to the present disclosure. Referring to FIG. 9D, in some embodiments, first subpixels sp1 in an Ax arc and second subpixels sp2 in an A(x+1) arc may have a same shape or different shapes, the Ax arc and the A(x+1) arc are directly adjacent to each other. In some embodiments, a wider end of a light emissive region of a respective first subpixel of the first subpixels sp1 in the Ax arc and a wider end of a light emissive region of a respective second subpixel of the second subpixels sp2 in the A(x+1) arc are adjacent to each other. For example, a narrower end of a light emissive region of the respective first subpixel of the first subpixels sp1 in the Ax arc is on a side of the wider end of a light emissive region of a respective first subpixel of the first subpixels sp1 in the Ax arc away from the respective second subpixel of the second subpixels sp2 in the A(x+1) arc; and a narrower end of the light emissive region of the respective second subpixel of the second subpixels sp2 in the A(x+1) arc is on a side of the wider end of a light emissive region of a respective second subpixel of the second subpixels sp2 in the A(x+1) arc away from the respective first subpixel of the first subpixels sp1 in the Ax arc. The respective second subpixel of the second subpixels sp2 in the A(x+1) arc is on a side of the respective first subpixel of the first subpixels sp1 in the Ax arc away from the same reference region RR. In some embodiments, the wider end of the light emissive region of the respective first subpixel of the first subpixels sp1 in the Ax arc has a convex shape protruding toward the wider end of the light emissive region of the respective second subpixel of the second subpixels sp2 in the A(x+1) arc. In some embodiments, the wider end of the light emissive region of the respective second subpixel of the second subpixels sp2 in the A(x+1) arc has a convex shape protruding toward the wider end of the light emissive region of the respective first subpixel of the first subpixels sp1 in the Ax arc.

FIG. 9E illustrates subpixels in an array substrate in some embodiments according to the present disclosure. Referring to FIG. 9E, in some embodiments, first subpixels sp1 in an Ax arc and second subpixels sp2 in an A(x+1) arc may have a same shape or different shapes, the Ax arc and the A(x+1) arc are directly adjacent to each other. In some embodiments, a wider end of a light emissive region of a respective first subpixel of the first subpixels sp1 in the Ax arc and a wider end of a light emissive region of a respective second subpixel of the second subpixels sp2 in the A(x+1) arc are adjacent to each other. For example, a narrower end of the light emissive region of the respective first subpixel of the first subpixels sp1 in the Ax arc is on a side of the wider end of a light emissive region of a respective first subpixel of the first subpixels sp1 in the Ax arc away from the respective second subpixel of the second subpixels sp2 in the A(x+1) arc; and a narrower end of the light emissive region of the respective second subpixel of the second subpixels sp2 in the A(x+1) arc is on a side of the wider end of a light emissive region of a respective second subpixel of the second subpixels sp2 in the A(x+1) arc away from the respective first subpixel of the first subpixels sp1 in the Ax arc. The respective second subpixel of the second subpixels sp2 in the A(x+1) arc is on a side of the respective first subpixel of the first subpixels sp1 in the Ax arc away from the same reference region RR. In some embodiments, the wider end of the light emissive region of the respective first subpixel of the first subpixels sp1 in the Ax arc has a concave shape recessing away from the wider end of the light emissive region of the respective second subpixel of the second subpixels sp2 in the A(x+1) arc. In some embodiments, the wider end of the light emissive region of the respective second subpixel of the second subpixels sp2 in the A(x+1) arc has a concave shape recessing away from the wider end of the light emissive region of the respective first subpixel of the first subpixels sp1 in the Ax arc.

Subpixels in the array substrate according to the present disclosure may have various appropriate shapes.

Referring to FIG. 9A, in some embodiments, at least some gate lines (e.g., GL2, GL (2N−2)) cross over subpixel regions of one or more arcs of subpixels; and at least some gate lines (e.g., GL1, GL3, GL (2N−1)) cross over an inter-subpixel region of the array substrate. As used herein, a subpixel region refers to a light emission region of a subpixel, such as a region corresponding to a pixel electrode in a liquid crystal display, or a region corresponding to a light emissive layer in an organic light emitting diode display panel. Optionally, a pixel may include a number of separate light emission regions corresponding to a number of subpixels in the pixel. Optionally, the subpixel region is a light emission region of a red color subpixel. Optionally, the subpixel region is a light emission region of a green color subpixel. Optionally, the subpixel region is a light emission region of a blue color subpixel. Optionally, the subpixel region is a light emission region of a white color subpixel. As used herein, an inter-subpixel region refers to a region between adjacent subpixel regions, such as a region corresponding to a black matrix in a liquid crystal display, or a region corresponding a pixel definition layer in an organic light emitting diode display panel. Optionally, the inter-subpixel region is a region between adjacent subpixel regions in a same pixel. Optionally, the inter-subpixel region is a region between two adjacent subpixel regions from two adjacent pixels. Optionally, the inter-subpixel region is a region between a subpixel region of a red color subpixel and a subpixel region of an adjacent green color subpixel. Optionally, the inter-subpixel region is a region between a subpixel region of a red color subpixel and a subpixel region of an adjacent blue color subpixel. Optionally, the inter-subpixel region is a region between a subpixel region of a green color subpixel and a subpixel region of an adjacent blue color subpixel.

FIG. 9I illustrates a layout of gate lines and data lines in an array substrate in some embodiments according to the present disclosure. Referring to FIG. 9I, all gate lines are disposed in inter-subpixel regions of the array substrate. Optionally, two adjacent gate lines are disposed in a same inter-subpixel region. For example, GL1 and GL2 are disposed in a same inter-subpixel region. By having this structure, aperture ratio of the array substrate can be improved as compared to the array substrate depicted in FIG. 9A.

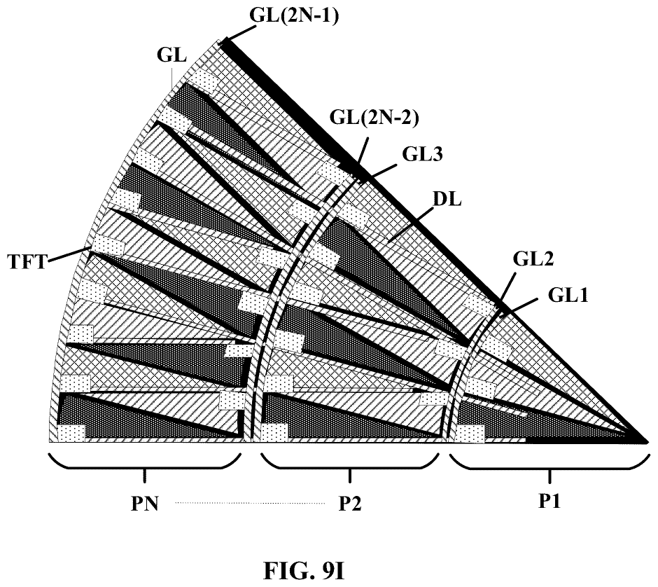

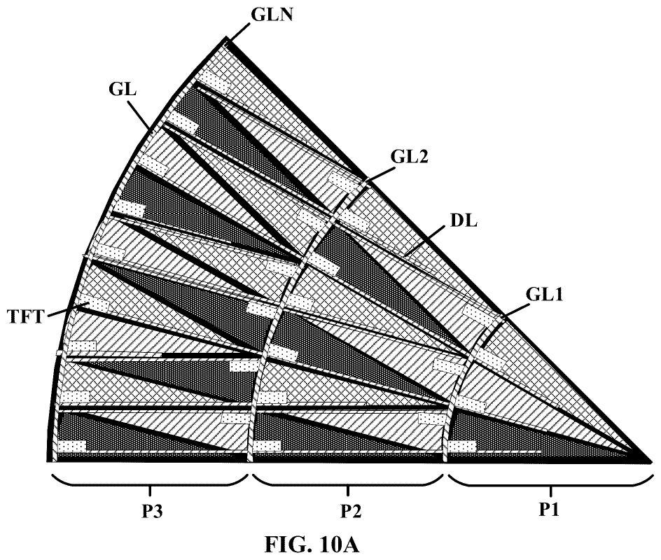

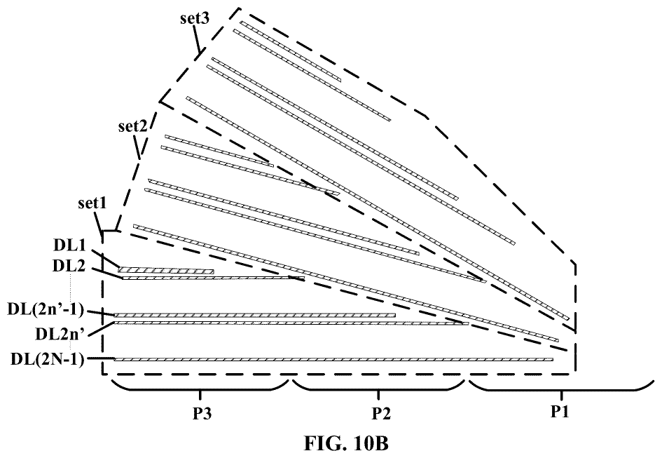

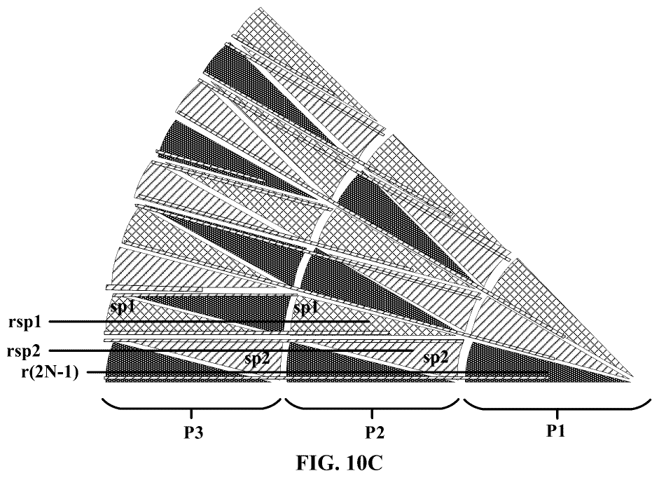

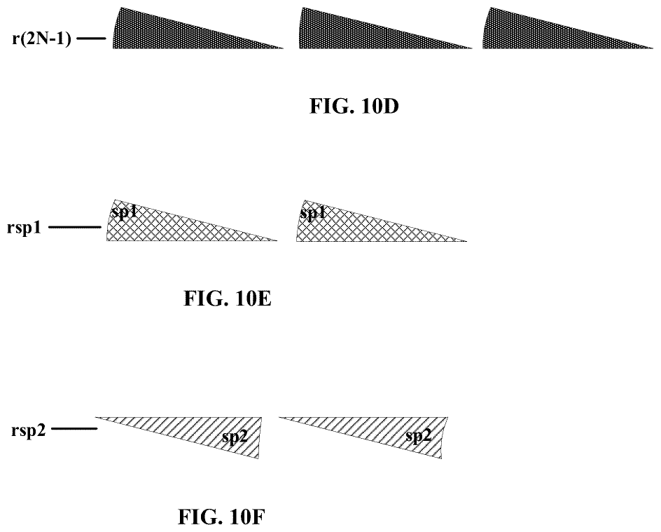

FIG. 10A illustrates a layout of gate lines and data lines in an array substrate in some embodiments according to the present disclosure. Referring to FIG. 10A, the array substrate in some embodiments includes N number of portions (P1 to PN). In some embodiments, the array substrate includes N number of gate lines and (J*(2N−1)) number of data lines. J stands for a number of subpixels in a 1st portion of the N number of portions. As shown in FIG. 10A, in some embodiments, a respective gate line of (N−1) number of gate line out of the N number of gate lines is between two adjacent portions of the N number of portions. For example, a 1st gate line GL1 is between the 1st portion P1 and the 2nd portion P2; a 2nd gate line is between the 2nd portion P2 and the 3rd portion P3. The respective gate line is configured to provide gate driving signals to the two adjacent portions of the N number of portions. For example, the 1 st gate line GL1 is configured to provide gate driving signals to the 1st portion P1 and the 2nd portion P2; the 2nd gate line is configured to provide gate driving signals to the 2nd portion P2 and the 3rd portion P3.

In some embodiments, the (J*(2N−1)) number of data lines comprise J number of sets of data lines, a respective set of the J number of sets of data lines comprising (2N−1) number of data lines. FIG. 10B illustrates a layout of data lines in the array substrate depicted in FIG. 10A. Referring to FIG. 10A and FIG. 10B, in one example, a number of subpixels in a 1st portion P1 of the N number of portions is 3, e.g., J=3. The (J*(2N−1)) number of data lines includes three sets of data lines, e.g., set1, set2, set3. A respective set of the J number of sets of data lines includes (2N−1) number of data lines. For example, the first set of data line set1 includes (2N−1) number of data lines, DL1, DL2, . . . , DL (2n′−1), DL2n′, . . . , DLN.

In some embodiments, a (2n′−1)-th data line in the respective set is configured to provide data signals to one or more subpixels in n′ number of portions of the N number of portions, 1<n′<N. In one example depicted in FIG. 10A and FIG. 10B, N=3, n′=2; a 3rd data line in the respective set is configured to provide data signals to one or more subpixels in two portions (P2 and P3) of the N number of portions. In another example, N=3, n′=1; a 1st data line DL1 in the respective set is configured to provide data signals to one or more subpixels in one portion (P3) of the N number of portions.

In some embodiments, a 2n′-th data line in the respective set is configured to provide data signals to one or more subpixels in n′ number of portions of the N number of portions. In one example depicted in FIG. 10A and FIG. 10B, N=3, n′=2; a fourth data line in the respective set is configured to provide data signals to one or more subpixels in two portions (P2 and P3) of the N number of portions. In another example, N=3, n′=1; a 2nd data line DL2 in the respective set is configured to provide data signals to one or more subpixels in one portion (P3) of the N number of portions.

FIG. 10C illustrates rows of subpixels connected to a respective set of data line in an array substrate in some embodiments according to the present disclosure. In some embodiments, referring to FIG. 10A to FIG. 10C, a (2N−1)-th data line in the respective set (e.g., set 1) is configured to provide data signals to a row of subpixels r (2N−1) in the N number of portions, respectively. The (2n′−1)-th data line DL (2n′−1) in the respective set is configured to provide data signals to a row of first subpixels rsp1 in n′ number of portions of the N number of portions, respectively. For example, when n′=2, a 3rd data line in the respective set is configured to provide data signals to a row of first subpixels rsp1 in two portions (P2 and P3) of the N number of portions, respectively. The 2n′-th data line DL2n′ in the respective set is configured to provide data signals to a row of second subpixels rsp2 in n′ number of portions of the N number of portions, respectively. For example, when n′=2, a fourth data line in the respective set is configured to provide data signals to a row of second subpixels rsp2 in two portions (P2 and P3) of the N number of portions, respectively. FIG. 10D illustrates a row of subpixels r (2N−1) in some embodiments according to the present disclosure. FIG. 10E illustrates a row of first subpixels rsp1 in n′ number of portions of the N number of portions, respectively. FIG. 10F illustrates a row of second subpixels rsp2 in n′ number of portions of the N number of portions, respectively.

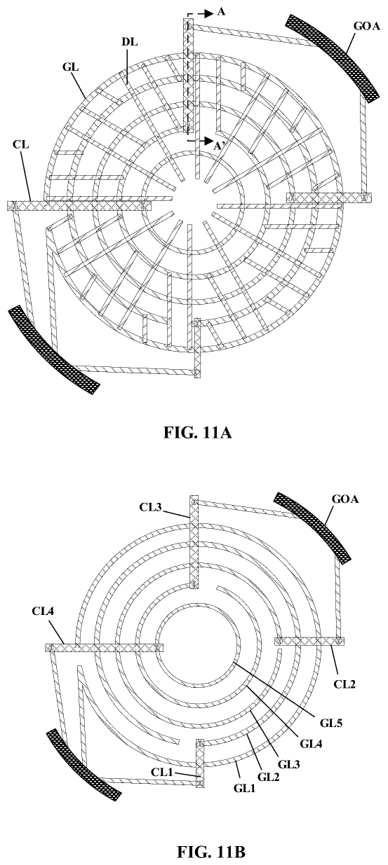

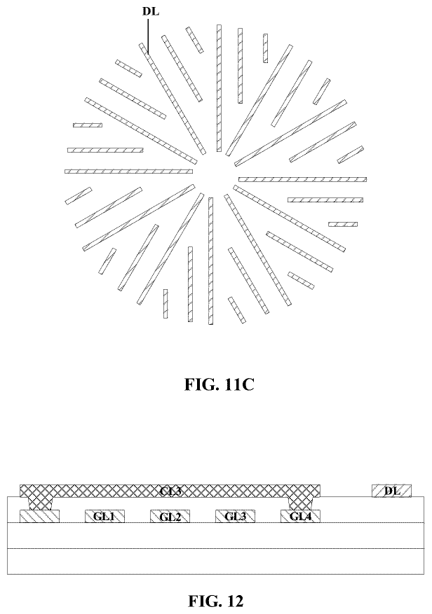

FIG. 11A illustrates a layout of signal lines in an array substrate in some embodiments according to the present disclosure. FIG. 11B illustrates a layout of gate lines in an array substrate in some embodiments according to the present disclosure. FIG. 11C illustrates a layout of data lines in an array substrate in some embodiments according to the present disclosure. The layout of signal lines depicted in FIG. 11A to FIG. 11C may be applicable to an array substrate depicted, e.g., in FIG. 1, FIG. 6A, FIG. 9A, or FIG. 10A. Referring to FIG. 11A to FIG. 11C, the array substrate in some embodiments includes a plurality of data lines DL, a plurality of gate lines GL, one or more gate-on-array GOA configured to provide gate driving signals to the plurality of gate lines, and a plurality of connecting lines CL.

In some embodiments, the array substrate includes M number of gate lines (e.g., GL1, GL2, GL3, GL4, and GL5) arranged as M number of partial circles surrounding the same reference region; and (M−1) number of connecting lines (e.g., CL1, CL2, CL3, and CL4). The (M−1) number of connecting lines are in a layer different from the M number of gate lines.

In some embodiments, a i-th connecting line of the (M−1) number of connecting lines electrically connects a (i+1)-th gate line to a gate-on-array, 1≤i≤(M−1). For example, CL1 electrically connects GL2 to a gate-on-array; CL2 electrically connects GL3 to a gate-on-array; CL3 electrically connects GL4 to a gate-on-array; and CL4 electrically connects GL5 to a gate-on-array.

In some embodiments, the i-th connecting line crosses over i number of gate lines. For example, CL1 crosses over one gate line (GL1); CL2 crosses over two gate lines (GL1 and GL2); CL3 crosses over three gate lines (GL1, GL2, GL3); and CL4 crosses over four gate lines (GL1, GL2, GL3, and GL4).

FIG. 12 is a cross-sectional view along an A-A′ line in FIG. 11A. Referring to FIG. 11A and FIG. 12, in some embodiments, the plurality of connecting lines CL are in a same layer as the plurality of data lines DL.

The array substrate according to the present disclosure is particularly advantageous for making display panels having curved edges such as a round display panel. In related display panels, subpixels are typically made to have a rectangular shape. In forming the curved edges of related display panels, subpixels adjacent to the curved edges have to be cut. Segmentations of rectangular subpixels along the curved edges often results in subpixels of different colors (e.g., red subpixels, green subpixels, and blue subpixels) having quite different areas, or even missing subpixels of one or more color along the curved edges. When a black matrix having an arc-shaped edge is used along the curved edges, the related display panels are prone to rainbow pattern defects. To obviate the rainbow pattern defects, a black matrix may be coated on the segmented subpixels along the curved edges. However, this implementation results in jagged edge defects in the related display panels. Thus, in related display panels, it is difficult to obviate the rainbow pattern defects and the jagged edge defects at the same time. Alternatively, subpixels along the curved edges of the related display panels may be made to have a smaller size. This implementation, however, still cannot completely obviate the rainbow pattern defects and the jagged edge defects. Further, making subpixels along the curved edges to have a smaller size results in an appearance of “local dashes along the edges,” adversely affecting display quality.

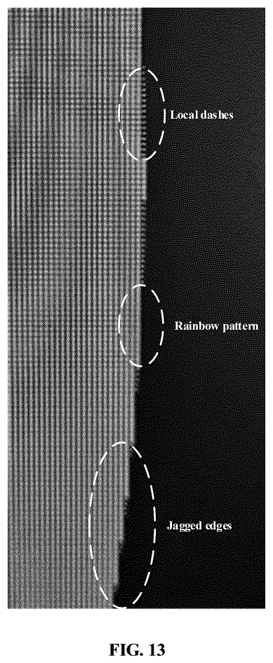

FIG. 13 illustrates several defects along a curved edge in a related display panel. The array substrate according to the present disclosure effectively obviates these defects.

In another aspect, the present invention provides a display apparatus, including the array substrate described herein or fabricated by a method described herein, and one or more integrated circuits connected to the array substrate. Examples of appropriate display apparatuses include, but are not limited to, an electronic paper, a mobile phone, a tablet computer, a television, a monitor, a notebook computer, a digital album, a GPS, etc. Optionally, the display apparatus is a liquid crystal display apparatus. Optionally, the display apparatus is an organic light emitting diode display apparatus. Optionally, the display apparatus is a micro light emitting diode display apparatus. Optionally, the display apparatus is a mini light emitting diode display apparatus.

The display apparatus may have various appropriate shapes. Examples of appropriate shapes of the display apparatus includes a circular shape, a square shape, a rectangular shape, an elliptical shape, a triangular shape, a polygonal shape, and an irregular shape.

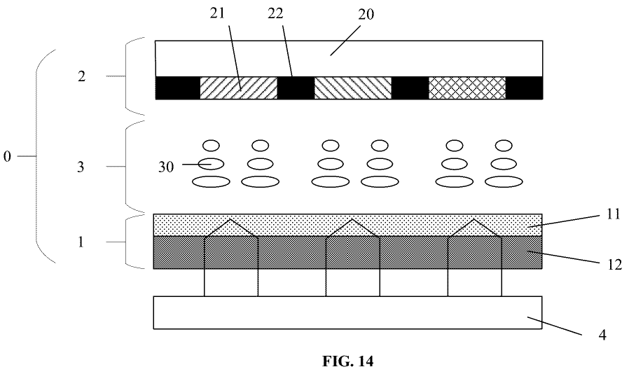

In some embodiments, the display apparatus is a liquid crystal display apparatus. FIG. 14 is a diagram illustrating the structure of a liquid crystal display apparatus in some embodiments according to the present disclosure. Referring to FIG. 14, the liquid crystal display apparatus in some embodiments includes a liquid crystal display panel 0 and a backlight module 4. In some embodiments, the liquid crystal display panel 0 includes an array substrate 1, a counter substrate 2, and a liquid crystal layer 3 between the array substrate 1 and the counter substrate 2. The liquid crystal layer 3 includes liquid crystal molecules 30 configured to transition between a light transmissive state and a light blocking state. The counter substrate 2 in some embodiments includes a base substrate 20, a black matrix layer 22 and a color filter layer 21 on the base substrate 20. The array substrate 1 includes a base substrate 12, and a thin film transistor substrate 11 on the base substrate 12.

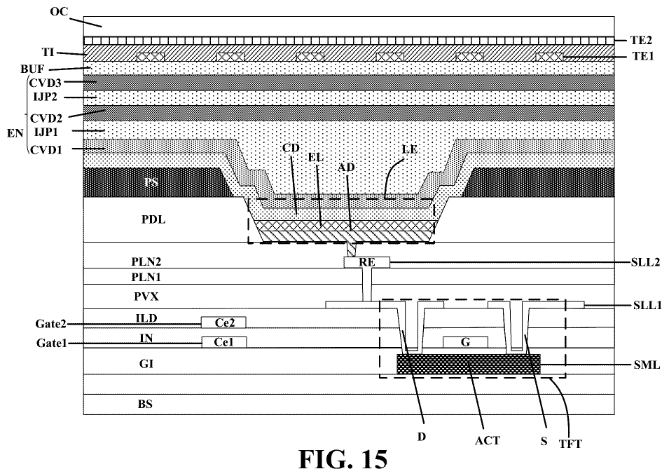

The display apparatus according to the present disclosure is not limited to liquid crystal display apparatus, but may be various appropriate types of display apparatus. In some embodiments, the display apparatus is a light emitting diode display apparatus. FIG. 15 illustrates a detailed structure in a display area in a light emitting diode display apparatus in some embodiments according to the present disclosure. Referring to FIG. 15, the display apparatus in the display area in some embodiments includes a base substrate BS (e.g., a flexible base substrate); an active layer ACT of a respective one of a plurality of thin film transistors TFT on the base substrate BS; a gate insulating layer GI on a side of the active layer ACT away from the base substrate BS; a gate electrode G and a first capacitor electrode Ce1 (both are parts of a first gate metal layer) on a side of the gate insulating layer GI away from the base substrate BS; an insulating layer IN on a side of the gate electrode G and the first capacitor electrode Ce1 away from the gate insulating layer GI; a second capacitor electrode Ce2 (a part of a second gate metal layer) on a side of the insulating layer IN away from the gate insulating layer GI; an inter-layer dielectric layer ILD on a side of the second capacitor electrode Ce2 away from the gate insulating layer GI; a source electrode S and a drain electrode D (parts of a first SD metal layer) on a side of the inter-layer dielectric layer ILD away from the gate insulating layer GI; a passivation layer PVX on a side of the source electrode S and the drain electrode D away from the inter-layer dielectric layer ILD; a first planarization layer PLN1 on a side of the passivation layer PVX away from the inter-layer dielectric layer ILD; a second planarization layer PLN2 on side of the first planarization layer PLN1 away from the passivation layer PVX; a relay electrode RE (part of a second SD metal layer) on a side of the second planarization layer PLN2 away from the first planarization layer PLN1; a pixel definition layer PDL defining a subpixel aperture and on a side of the second planarization layer PLN2 away from the base substrate BS; and a light emitting element LE in the subpixel aperture. The light emitting element LE includes an anode AD on a side of the second planarization layer PLN2 away from the first planarization layer PLN1; a light emitting layer EL on a side of the anode AD away from the second planarization layer PLN2; and a cathode layer CD on a side of the light emitting layer EL away from the anode AD. The display apparatus in the display area further includes an encapsulating layer EN encapsulating the light emitting element LE, and on a side of the cathode layer CD away from the base substrate BS.

The encapsulating layer EN in some embodiments includes a first inorganic encapsulating sub-layer CVD1 on a side of the cathode layer CD away from the base substrate BS, a first organic encapsulating sub-layer IJP1 on a side of the first inorganic encapsulating sub-layer CVD1 away from the base substrate BS, a second inorganic encapsulating sub-layer CVD2 on a side of the first organic encapsulating sub-layer IJP1 away from the base substrate BS, a second organic encapsulating sub-layer IJP2 on a side of the second inorganic encapsulating sub-layer CVD2 away from the base substrate BS, and a third inorganic encapsulating sub-layer CVD3 on a side of the second organic encapsulating sub-layer IJP2 away from the base substrate BS.

The display apparatus in the display area further includes a buffer layer BUF on a side of the encapsulating layer EN away from the base substrate BS; a first touch electrode layer TE1 on a side of the buffer layer BUF away from the encapsulating layer EN; a touch insulating layer TI on a side of the first touch electrode layer TE1 away from the buffer layer BUF; a second touch electrode layer TE2 on a side of the touch insulating layer TI away from the buffer layer BUF; and an overcoat layer OC on a side of the second touch electrode layer TE2 away from the touch insulating layer TI.

Referring to FIG. 15, the display apparatus includes a semiconductor material layer SML, a first gate metal layer Gate1, a second gate metal layer Gate2, a first signal line layer SLL1, and a second signal line layer SLL2. The display apparatus further includes an insulating layer IN between the first gate metal layer Gate1 and the second gate metal layer Gate2; an inter-layer dielectric layer ILD between the second conductive layer Gate2 and the first signal line layer SLL1; and at least a passivation layer PVX or a planarization layer PLN between the first signal line layer SLL1 and the second signal line layer SLL2.

In another aspect, the present disclosure provides a method of fabricating an array substrate. In some embodiments, the method includes forming, in at least a region, a plurality of subpixels. Optionally, a light emissive region of a respective subpixel of the plurality of subpixels is formed to have a first end and a second end, the second end being on a side of the first end away from a same reference region with respect to the plurality of subpixels in the region; directions respectively from second ends to first ends of the plurality of subpixels substantially point toward the same reference region. Optionally, in the region, pixel-per-inch (PPI) is substantially the same in accordance with a distance away from the same reference region. Optionally, in the region, forming the plurality of subpixels comprise forming first subpixels of a first orientation and forming second subpixels of a second orientation. Optionally, a width of a first light emissive region of a respective first subpixel of the first subpixels increases from the first end to the second end. Optionally, a width of a second light emissive region of a respective second subpixel of the second subpixels decreases from the first end to the second end. Optionally, the first orientation and the second orientation are substantially opposite to each other.

Various appropriate conductive materials and various appropriate fabricating methods may be used to make the gate lines, the data lines, and the connecting lines. For example, a conductive material may be deposited on the substrate by a plasma-enhanced chemical vapor deposition (PECVD) process and patterned. Examples of appropriate conductive materials for making the gate lines, the data lines, and the connecting lines include, but are not limited to, aluminum, copper, molybdenum, chromium, aluminum copper alloy, copper molybdenum alloy, molybdenum aluminum alloy, aluminum chromium alloy, copper chromium alloy, molybdenum chromium alloy, copper molybdenum aluminum alloy, and the like.

In some embodiments, the method includes forming N number of portions sequentially arranged in the region, N being an integer greater than 2. Optionally, an (n+1)-th portion is formed on a side of an n-th portion away from the same reference region, 1≤n≤(N−1). Optionally, subpixels of the n-th portion that are directly adjacent to the (n+1)-th portion and subpixels of the (n+1)-th portion that are directly adjacent to the n-th portion, where wider ends of light emissive regions of the subpixels of the n-th portion that are directly adjacent to the (n+1)-th portion are directly adjacent to wider ends of light emissive regions of subpixels of the (n+1)-th portion that are directly adjacent to the n-th portion, are formed to have different orientations.

In some embodiments, multiple adjacent subpixels in a respective portion of the N number of portions form a pixel.

In some embodiments, the N number of portions are arranged along N number of arcs, respectively. Optionally, the N number of arcs are formed at least partially surrounding the same reference region.

In some embodiments, the N number of arcs are N number of circles, respectively. Optionally, the same reference region is a same central region with respect to N number of circles along which the N number of portions are arranged, respectively. Optionally, the N number of circles substantially surround the same central region.

In some embodiments, forming a respective portion of the N number of portions includes forming one or more arcs of subpixels. Optionally, forming the array substrate includes forming X number of arcs of subpixels at least partially surrounding the same reference region, X being an integer greater than 2. Optionally, subpixels respectively from any two directly adjacent arcs of subpixels are formed to have different orientations.

In some embodiments, a 1st portion of the N number of portions is formed to include one arc of subpixels, the n-th portion is formed to include two arcs of subpixels, and an N-th portion is formed to include two arcs of subpixels, and X=2(N−1)+1.

In some embodiments, a 1st portion of the N number of portions is formed to include one arc of subpixels. Optionally, adjacent subpixels along the one arc of subpixels have a same orientation.

In some embodiments, a ratio of a number of subpixels having first orientations to a number of subpixels having second orientations in the n-th portion is greater than a ratio of a number of subpixels having first orientations to a number of subpixels having second orientations in the (n+1)-th portion.

In some embodiments, a ratio of a number of subpixels having first orientations to a number of subpixels having second orientations in the n-th portion is in a range of (n−0.5):(n−1) to (n+0.5):(n−1), e.g., n: (n−1).

In some embodiments, the subpixels of the n-th portion that are directly adjacent to the (n+1)-th portion are formed to have the first orientation; and the subpixels of the (n+1)-th portion that are directly adjacent to the n-th portion are formed to have the second orientation.

In some embodiments, forming at least a m-th portion of the N number of portions includes forming a first sub-portion and a second sub-portion, the second sub-portion being on a side of the first sub-portion away from the same reference region, 1<m<(N−1). Optionally, subpixels of the first sub-portion and subpixels of the second sub-portion have different orientations.

In some embodiments, the subpixels of the first sub-portion are formed to have the second orientation. Optionally, the subpixels of the second sub-portion are formed to have the first orientation.

In some embodiments, a number of subpixels formed in the n-th portion is S*I*(2n−1); S stands for a number of subpixels in a respective pixel; and I stands for a number of subpixels in a 1st portion of the N number of portions divided by S, the 1st portion being a portion of the N number of portions closest to the same reference region.

In some embodiments, the method includes forming at least N number of gate lines and at least (J*N) number of data lines. Optionally, a respective gate line of (N−1) number of gate line out of the N number of gate lines is formed between two adjacent portions of the N number of portions. Optionally, J stands for a number of subpixels in a 1st portion of the N number of portions, the 1st portion being a portion of the N number of portions closest to the same reference region.

In some embodiments, the method includes forming (2N−1) number of gate lines and (J*N) number of data lines.

In some embodiments, a 1st gate line of the (2N−1) number of gate lines is configured to provide gate driving signals to the subpixels in the 1st portion. Optionally, a respective portion of a 2nd portion to the N-th portion of the N number of portions is configured to receive gate driving signals from two gate lines.

In some embodiments, forming the (J*N) number of data lines includes forming J number of sets of data lines, a respective set of the J number of sets of data lines comprising N number of data lines. Optionally, an n-th data line in the respective set is configured to provide data signals to one or more subpixels in n number of portions of the N number of portions, 1≤n≤N.

In some embodiments, an N-th data line of the N number of data lines in the respective set is configured to provide data signals to a row of subpixels in the N number of portions, respectively. Optionally, a 1st data line of the N number of data lines in the respective set is configured to provide data signals to two subpixels in the N-th portion of the N number of portions. Optionally, an n′-th data line of the N number of data lines in the respective set is configured to provide data signals to two rows of subpixels in n′ number of portions of the N number of portions, respectively, 1<n′<N.

In some embodiments, a respective set of the J number of sets of data lines comprises N number of data lines. Optionally, in a j′-th set of the J number of sets of data lines, 1<j′<J, two subpixels in a same portion, each having at least 40% of an elongated side directly adjacent to the N-th data line, have a same orientation. Optionally, in the j′-th set of the J number of sets of data lines, 1<j′<J, two subpixels in a same portion, each having at least 40% of an elongated side directly adjacent to an n″-th data line of the N number of data lines, 1≤n″ <N.

In some embodiments, the method includes forming N number of gate lines and (J*(2N−1)) number of data lines.

In some embodiments, the respective gate line is configured to provide gate driving signals to the two adjacent portions of the N number of portions.

In some embodiments, forming the (J*(2N−1)) number of data lines includes forming I number of sets of data lines, a respective set of the I number of sets of data lines comprising (2N−1) number of data lines. Optionally, a (2n′−1)-th data line in the respective set is configured to provide data signals to one or more subpixels in n′ number of portions of the N number of portions, 1<n′<N. Optionally, a 2n′-th data line in the respective set is configured to provide data signals to one or more subpixels in n′ number of portions of the N number of portions.

In some embodiments, a 1st data line in the respective set is configured to provide data signals to a row of subpixels in the N number of portions, respectively. Optionally, the (2n′−1)-th data line in the respective set is configured to provide data signals to a row of first subpixels in n′ number of portions of the N number of portions, respectively, 1<n′<N. Optionally, the 2n′-th data line in the respective set is configured to provide data signals to a row of second subpixels in n′ number of portions of the N number of portions, respectively.

In some embodiments, the method includes forming M number of gate lines arranged is M number of partial circles surrounding the same reference region; and forming (M−1) number of connecting lines. Optionally, the (M−1) number of connecting lines are in a layer different from the M number of gate lines. Optionally, a i-th connecting line of the (M−1) number of connecting lines electrically connects a (i+1)-th gate line to a gate-on-array, 1≤i≤(M−1). Optionally, the i-th connecting line crosses over i number of gate lines.

In some embodiments, the (M−1) number of connecting lines are formed in a same layer as the at least (J*N) number of data lines.

In some embodiments, respective areas of the subpixels in the region are substantially the same.

In some embodiments, a number of subpixels in the N number of portions increases in accordance with a distance away from the same reference region.

In some embodiments, a width of the same reference region is less than two times of a maximum length of a respective subpixel.

The foregoing description of the embodiments of the invention has been presented for purposes of illustration and description. It is not intended to be exhaustive or to limit the invention to the precise form or to exemplary embodiments disclosed. Accordingly, the foregoing description should be regarded as illustrative rather than restrictive. Obviously, many modifications and variations will be apparent to practitioners skilled in this art. The embodiments are chosen and described in order to explain the principles of the invention and its best mode practical application, thereby to enable persons skilled in the art to understand the invention for various embodiments and with various modifications as are suited to the particular use or implementation contemplated. It is intended that the scope of the invention be defined by the claims appended hereto and their equivalents in which all terms are meant in their broadest reasonable sense unless otherwise indicated. Therefore, the term “the invention”, “the present invention” or the like does not necessarily limit the claim scope to a specific embodiment, and the reference to exemplary embodiments of the invention does not imply a limitation on the invention, and no such limitation is to be inferred. The invention is limited only by the spirit and scope of the appended claims. Moreover, these claims may refer to use “first”, “second”, etc. following with noun or element. Such terms should be understood as a nomenclature and should not be construed as giving the limitation on the number of the elements modified by such nomenclature unless specific number has been given. Any advantages and benefits described may not apply to all embodiments of the invention. It should be appreciated that variations may be made in the embodiments described by persons skilled in the art without departing from the scope of the present invention as defined by the following claims. Moreover, no element and component in the present disclosure is intended to be dedicated to the public regardless of whether the element or component is explicitly recited in the following claims.

1. An array substrate, in at least a region, comprising a plurality of subpixels;
wherein a light emissive region of a respective subpixel of the plurality of subpixels has a first end and a second end, the second end being on a side of the first end away from a same reference region with respect to the plurality of subpixels in the region;
directions respectively from second ends to first ends of the plurality of subpixels substantially point toward the same reference region; and
in the region, pixel-per-inch (PPI) is substantially the same in accordance with a distance away from the same reference region;
wherein, in the region, the plurality of subpixels comprise first subpixels of a first orientation and second subpixels of a second orientation;
a width of a first light emissive region of a respective first subpixel of the first subpixels increases from the first end to the second end;
a width of a second light emissive region of a respective second subpixel of the second subpixels decreases from the first end to the second end; and
the first orientation and the second orientation are substantially opposite to each other.

2. The array substrate of claim 1, comprising N number of portions sequentially arranged in the region, N being an integer greater than 2;
wherein an (n+1)-th portion is on a side of an n-th portion away from the same reference region, 1≤n≤(N−1); and
subpixels of the n-th portion that are directly adjacent to the (n+1)-th portion and subpixels of the (n+1)-th portion that are directly adjacent to the n-th portion, where wider ends of light emissive regions of the subpixels of the n-th portion that are directly adjacent to the (n+1)-th portion are directly adjacent to wider ends of light emissive regions of subpixels of the (n+1)-th portion that are directly adjacent to the n-th portion, have different orientations.

3. (canceled)

4. The array substrate of claim 2, wherein a respective portion of the N number of portions comprises one or more arcs of subpixels;
the array substrate comprises X number of arcs of subpixels at least partially surrounding the same reference region, X being an integer greater than 2; and
subpixels respectively from any two directly adjacent arcs of subpixels have different orientations.

5. The array substrate of claim 4, wherein a 1st portion of the N number of portions comprises one arc of subpixels, the n-th portion comprises two arcs of subpixels, and an N-th portion comprises two arcs of subpixels, and X=2(N−1)+1.

6. (canceled)

7. The array substrate of claim 2, wherein a ratio of a number of subpixels having first orientations to a number of subpixels having second orientations in the n-th portion is greater than a ratio of a number of subpixels having first orientations to a number of subpixels having second orientations in the (n+1)-th portion.

8. The array substrate of claim 7, wherein a ratio of a number of subpixels having first orientations to a number of subpixels having second orientations in the n-th portion is in a range of (n−0.5):(n−1) to (n+0.5):(n−1).

9. (canceled)

10. The array substrate of claim 2, wherein at least a m-th portion of the N number of portions comprises a first sub-portion and a second sub-portion, the second sub-portion being on a side of the first sub-portion away from the same reference region, 1<m<(N−1); and
subpixels of the first sub-portion and subpixels of the second sub-portion have different orientations.

11. (canceled)

12. The array substrate of claim 2, wherein a number of subpixels in the n-th portion is S*I*(2n−1);
S stands for a number of subpixels in a respective pixel; and
I stands for a number of subpixels in a 1st portion of the N number of portions divided by S, the 1st portion being a portion of the N number of portions closest to the same reference region.

13. The array substrate of claim 2, comprising at least N number of gate lines and at least (J*N) number of data lines;
wherein a respective gate line of (N−1) number of gate line out of the N number of gate lines is between two adjacent portions of the N number of portions; and
J stands for a number of subpixels in a 1st portion of the N number of portions, the 1st portion being a portion of the N number of portions closest to the same reference region.

14. The array substrate of claim 13, comprising (2N−1) number of gate lines and (J*N) number of data lines.

15. The array substrate of claim 14, wherein a 1st gate line of the (2N−1) number of gate lines is configured to provide gate driving signals to the subpixels in the 1st portion; and
a respective portion of a 2nd portion to the N-th portion of the N number of portions is configured to receive gate driving signals from two gate lines.

16. The array substrate of claim 14, wherein the (J*N) number of data lines comprise J number of sets of data lines, a respective set of the J number of sets of data lines comprising N number of data lines; and
an n-th data line in the respective set is configured to provide data signals to one or more subpixels in n number of portions of the N number of portions, 1≤n≤N.

17. The array substrate of claim 16, wherein an N-th data line of the N number of data lines in the respective set is configured to provide data signals to a row of subpixels in the N number of portions, respectively;
a 1st data line of the N number of data lines in the respective set is configured to provide data signals to two subpixels in the N-th portion of the N number of portions; and
an n′-th data line of the N number of data lines in the respective set is configured to provide data signals to two rows of subpixels in n′ number of portions of the N number of portions, respectively, 1<n′<N.

18. The array substrate of claim 14, wherein a respective set of the J number of sets of data lines comprises N number of data lines;
in a j′-th set of the J number of sets of data lines, 1<j′<J, two subpixels in a same portion, each having at least 40% of an elongated side directly adjacent to the N-th data line, have a same orientation; and
in the j′-th set of the J number of sets of data lines, 1<j′<J, two subpixels in a same portion, each having at least 40% of an elongated side directly adjacent to an n″-th data line of the N number of data lines, have a same orientation, 1≤n″<N.

19. The array substrate of claim 13, comprising N number of gate lines and (J*(2N−1)) number of data lines.

20. The array substrate of claim 19, wherein the respective gate line is configured to provide gate driving signals to the two adjacent portions of the N number of portions.

21. The array substrate of claim 19, wherein the (J*(2N−1)) number of data lines comprise I number of sets of data lines, a respective set of the I number of sets of data lines comprising (2N−1) number of data lines;
a (2n′−1)-th data line in the respective set is configured to provide data signals to one or more subpixels in n′ number of portions of the N number of portions, 1<n′<N; and
a 2n′-th data line in the respective set is configured to provide data signals to one or more subpixels in n′ number of portions of the N number of portions.

22. The array substrate of claim 21, wherein a 1st data line in the respective set is configured to provide data signals to a row of subpixels in the N number of portions, respectively;
the (2n′−1)-th data line in the respective set is configured to provide data signals to a row of first subpixels in n′ number of portions of the N number of portions, respectively, 1<n′<N; and
the 2n′-th data line in the respective set is configured to provide data signals to a row of second subpixels in n′ number of portions of the N number of portions, respectively.

23. The array substrate of claim 13, comprising:
M number of gate lines arranged as M number of partial circles surrounding the same reference region; and
(M−1) number of connecting lines;
wherein the (M−1) number of connecting lines are in a layer different from the M number of gate lines;
a i-th connecting line of the (M−1) number of connecting lines electrically connects a (i+1)-th gate line to a gate-on-array, 1≤i≤(M−1); and
the i-th connecting line crosses over i number of gate lines.

24. (canceled)

25. (canceled)

26. (canceled)

27. (canceled)

28. A display apparatus, comprising the array substrate of claim 1, and one or more integrated circuits connected to the array substrate.

29. (canceled)
